(19) United States
(12) Patent Application Publication
(10) Pub. No.: US 2026/0066235 A1
(43) Pub. Date: Mar. 5, 2026

(54) DEVICE FOR PROVIDING A PLASMA

(71) Applicant: Thermal Processing Solutions GmbH, Braunau am Inn - Ranshofen (AT)

(72) Inventor: Werner WIGGIN, Köditz (DE)

(21) Appl. No.: 19/102,349

(22) PCT Filed: Aug. 8, 2023
(86) PCT No.: PCT/AT2023/060268

§ 371 Date: Feb. 7, 2025

(30) Foreign Application Priority Data
Aug. 9, 2022 (AT) A50614/2022

(51) Int. Cl. H01J 37/32

(52) U.S. Cl. CPC H01J 37/32449

(57) ABSTRACT

A device for providing a plasma, comprising at least one plasma-generating element with one inlet and one outlet for a gaseous fluid, wherein a first flow channel is arranged in the plasma-generating element, optionally a second flow channel which is arranged concentrically thereto and surrounds the first flow channel at least in sections, is arranged, the first flow channel being fluidically connected to a first connection for a gaseous fluid for forming a heated gas flow and/or a plasma flow, and the inlet of the plasma-generating element being fluidically connected to a conveying element, with which the gaseous fluid can be accelerated.

### RELATED APPLICATIONS

This is national stage under 35 U.S. C. § 371 of International Application No. PCT/US2023/060268, filed Aug. 8, 2023, which claims priority of Austrian Patent Application No. A50614/2022, filed Aug. 9, 2023.

### TECHNICAL FIELD

The field of the present disclosure relates to devices for providing a plasma, to devices for the thermal treatment of a substance, and to methods for operating a device for providing a plasma for generating a hot gas flow and/or a plasma flow for thermally treating a substance.

### BACKGROUND

The use of so-called plasma torches of various designs for melting substances, especially metals, is already documented in the state of the art.

For example, DE10 2020 202 484 A1 describes a device for melting metals whose melting temperature is less than 1000° C., in which a device for forming a plasma is arranged on a melting furnace, wherein the device is connected to an electrical power supply and at least one first supply for a plasma gas, with which the plasma can be formed, is connected to the device, and the device is designed, dimensioned, arranged and/or aligned in such a way that the formed plasma is arranged at a distance from the metal as a melting material, and at the same time a hot gas flow can be formed with the plasma, which is aligned in the direction of the molten material, and a melting tank or a crucible is arranged in the melting furnace to receive the molten metal.

An induction plasma torch is known from EP 1 433 366 A1 comprising a tubular torch body having proximal and distal ends, and including a cylindrical inner surface having a first diameter, a plasma confinement tube made of material having a high thermal conductivity, defining an axial chamber in which high temperature plasma is confined, and including a cylindrical outer surface having a second diameter slightly smaller than the first diameter, the plasma confinement tube being mounted within the tubular torch body, and the cylindrical inner and outer surfaces being coaxial to define between said inner and outer surfaces a thin annular chamber of uniform thickness, a gas distributor head mounted on the proximal end of the torch body for supplying at least one gaseous substance into the axial chamber defined by the plasma confinement tube, a cooling fluid supply connected to the thin annular chamber for establishing a high velocity flow of cooling fluid in said thin annular chamber, the high thermal conductivity of the material forming the confinement tube and the high velocity flow of cooling fluid both contributing in efficiently transferring heat from the plasma confinement tube, heated by the high temperature plasma, into the cooling fluid to thereby efficiently cool the confinement tube, a first power supply having a higher frequency output, a second power supply having a lower frequency output including first and second terminals, a series of induction coils mounted to the tubular torch body generally coaxial with said tubular torch body between the proximal and distal ends of the torch body, the series of induction coils comprising, a first induction coil connected to the higher frequency output of the first power supply to inductively apply energy to the at least one gaseous substance supplied to the axial chamber; and a plurality of second induction coils between the first induction coil and the distal end of the tubular torch body, the second induction coils having respective terminals; and an interconnection circuit interposed between said first and second terminals of the lower frequency output of the second power supply and the terminals of the second induction coils, to connect the second induction coils in a series and/or parallel arrangement between said first and second terminals in order to substantially match an input impedance of the second induction coils with an output impedance of the second power supply, and inductively apply energy to said at least one gaseous substance supplied to the axial chamber.

US 2004/107796 A1 describes a plasma-assisted melting method, comprising: forming a plasma in a cavity by exposing a first gas to electromagnetic radiation having a frequency of less than about 333 GHz in the presence of a plasma catalyst; heating a second gas with the plasma; adding a solid to a melting container; and directing the heated second gas toward the solid sufficient to at least melt the solid.

An induction plasma torch is known from DE 69216970 T2, which comprises: a tubular torch body including a cylindrical inner surface having a first diameter; a plasma confinement tube formed of thermally conductive ceramic material and including a first end, a second end, and a cylindrical outer surface having a second diameter smaller than the first diameter; wherein the plasma confinement tube is mounted in the tubular torch body and forms an annular chamber between the cylindrical inner and outer surfaces; a gas distributor attached to the tubular torch body at the first end of the plasma confinement tube and supplying at least one gaseous substance to the plasma confinement tube, the at least one gaseous substance flowing through the plasma confinement tube from the first end thereof toward the second end thereof; an induction coil to which an electric current is supplied to inductively energize the at least one gaseous substance flowing through the plasma confinement tube to produce and maintain plasma in the confinement tube, the induction coil being coaxial with the cylindrical inner and outer surfaces of the annular chamber; and an apparatus for establishing a flow of cooling fluid in the annular chamber; wherein the induction coil is embedded in the tubular burner body, and the cylindrical inner and outer surfaces are machined and coaxial so that the annular chamber has a uniform thickness.

EP 3 314 989 B1 describes an induction plasma torch, comprising: a tubular torch body having an upstream section and a downstream section, the upstream and downstream sections defining respective inner surfaces; and a plasma confinement tube disposed within the tubular torch body, coaxial with the tubular torch body, and having an inner surface of constant inner diameter and an outer surface; and a tubular insert mounted to the inner surface of the downstream section of the tubular torch body, the tubular insert having an inner surface; and an annular channel defined between the inner surface of the upstream section of the tubular torch body and the inner surface of the tubular insert, and the outer surface of the plasma confinement tube, the annular channel being configured to conduct a cooling fluid for cooling the plasma confinement tube ; and wherein the plasma confinement tube has a tubular wall with a thickness tapering off in an axial direction of plasma flow over at least a section of the plasma confinement tube.

EP 2 671 430 B1 describes an induction plasma torch, comprising: a tubular torch body having an inner surface; a plasma confinement tube disposed in the tubular torch body coaxial with said tubular torch body, the plasma confinement tube having an outer surface; a gas distributor head disposed at one end of the plasma confinement tube and structured to supply at least one gaseous substance into the plasma confinement tube; an inductive coupling member for applying energy to the gaseous substance to produce and sustain plasma in the plasma confinement tube; and a capacitive shield including a film of conductive material applied to the outer surface of the plasma confinement tube or the inner surface of the tubular torch body, wherein the film of conductive material is segmented into axial strips and the axial strips are interconnected at one end, and wherein the inductive coupling member is embedded within the tubular torch body and axial grooves are formed in the outer surface of the plasma confinement tube or the inner surface of the tubular torch body, each one of the axial grooves being interposed between a pair of laterally adjacent axial strips.

A need remains for an improved way of thermally treating a substance.

### SUMMARY

An improved device for providing a plasma includes at least one plasma-generating element with one inlet and one outlet for a gaseous fluid, wherein a first flow channel is arranged in the plasma-generating element, optionally a second flow channel, which is arranged concentrically thereto and surrounds the first flow channel at least in sections, and the first flow channel being fluidically connected to a first connection for a gaseous fluid for configuring a heated gas flow and/or a plasma flow, and the inlet of the plasma-generating element is fluidically connected to a conveying element with which the gaseous fluid can be accelerated.

In another embodiment, a device for thermal treatment of a substance, includes at least once such the device for providing a plasma.

According to yet another embodiment, a method for operating a device for providing a plasma for generating a hot gas flow and/or a plasma flow for thermally treating a substance, comprises the steps of: supplying a gaseous fluid into a plasma-generating element of the device, generating a plasma in the plasma-generating element; providing a hot fluid flow by the plasma, possibly by heating the gaseous fluid with the plasma to produce a hot gas, wherein the hot fluid flow is directed outside the plasma-generating element onto the substance to be treated, and wherein the gaseous fluid is accelerated before supplying it into the plasma-generating element.

The advantage here is that the acceleration can improve the introduction of the gaseous fluid into the plasma-generating element. This in turn can prevent overheating of the plasma-generating element and/or the device on which the plasma-generating element is arranged and/or the material to be thermally treated in the area of the plasma. The acceleration is particularly advantageous if the plasma-generating element is supplied with a mixture of gaseous fluids, preferably a circulating gas and a fresh gas, as the other gas flow can also be “entrained” with the accelerated gas flow. In addition, the increase in pressure that may accompany the acceleration can generate an overpressure in the system, which prevents the penetration of oxygen-containing gases from the environment of the device and thus oxidative problems in the device for the thermal treatment of a substance.

According to an embodiment variant, it may be provided that the plasma-generating element is fluidically connected to the gas supply device. This makes it easier to provide the gaseous fluids or to regulate the volume flow of these gaseous fluids to the plasma-generating element.

According to an embodiment variant, the gas supply device may have a fresh gas supply and/or a circulating gas supply for a circulating gas, which can simplify the gas flows in the system, especially if gaseous fluid is supplied to the plasma-generating element at several different points.

Preferably, according to an embodiment variant, the conveying element is arranged in a circulating gas flow for the circulating gas, which is fluidically connected to the outlet of the plasma-generating element. Since the portion of circulating gas in the device should be maximized in order to improve the energy balance, the above-mentioned effects can be further improved with this embodiment variant.

According to a further embodiment variant, it may be provided that the conveying element is a jet pump. This has the advantage that the gaseous fluid, in particular the circulating gas, can be hotter, as a jet pump can be operated without moving parts.

According to a further embodiment variant, the jet pump may be provided with a propellant connection that is connected to the fresh gas supply. The fresh gas supplied to the plasma-generating element can thus also take over the function of the propellant, which can reduce costs by reducing the quantities of fluid required.

According to a further embodiment variant, it may be provided that the jet pump is a controllable jet pump with a regulation of the volume or quantity flow of fresh gas, which can simplify the regulation and/or control of the device for generating a plasma and the device for thermal treatment of a substance.

According to another embodiment variant, it may be provided that the inlet of the plasma-generating element is fluidically connected to a further fresh gas supply. It is thus possible to reduce the volume flow of fresh gas in the jet pump while maintaining the same volume flow of circulating gas. On the other hand, other conveying elements may also be used for circulating the circulating gas.

According to an embodiment variant, it is advantageous if a heat exchanger is arranged upstream of the conveying element in the direction of flow of the gaseous fluid, as this allows the temperature of the gaseous fluid to be reduced and, as a result, conveying elements with a lower thermal load, such as a fan, can also be used. The heat exchanger also allows the energy extracted from the gaseous fluid to be reused.

It is also advantageous if, according to a further embodiment variant, a further heat exchanger is arranged in the further fresh gas supply, so that the fresh gas can already be introduced into the plasma-generating element at a higher temperature. The use of a heat exchanger enables the waste heat from another process to be used.

According to an embodiment variant, the further heat exchanger may be fluidically connected to the heat exchanger upstream of the conveying element, so that preheating can take place with the waste heat from the process itself. The distance between the heat exchangers is relatively small, which can improve the energy balance of the device.

According to another embodiment variant, the conveying element may also be a fan or a turbine, which makes it possible to dispense with the supply of a propellant fluid, while at the same time enabling good controllability of the volume flow.

According to an embodiment variant of the process, a further gaseous fluid may be added to the gaseous fluid in order to influence the process conditions.

However, according to a further embodiment variant of the method, the further gaseous fluid may also be used to adjust or regulate the temperature and/or the position of a plasma torch. Local temperature increases can thus be minimized and the overall heat transfer improved.

According to an embodiment variant of the method, it may be provided that the plasma is generated inductively with at least one electric induction coil, and in that, furthermore, the temperature of the induction coil and/or a temperature rise of a cooling liquid for the induction coil and/or a temperature change of the wall of the plasma-generating element in the region of the hot gas outlet is measured and the volume flow of the central gas flow is changed on the basis of this measured value in the event of a temperature change. The efficiency of the device for generating a plasma can thus be improved, for example by increasing or reducing the volume flow rate of circulating gas.

For the above reasons, it is advantageous if, according to an embodiment variant of the method, it is provided that this further comprises the steps of supplying a fresh gas flow to a gas supply device of the plasma-generating element, supplying a circulating gas flow from a treatment chamber in which the substance is thermally treated to the gas supply device, a jet pump being used for supplying the circulating gas flow, which is operated with a fresh gas flow as propellant gas.

According to an embodiment variant of the method, it may be provided that the volume flow of the circulating gas flow is regulated with the volume flow of fresh gas supplied to the jet pump, which can subsequently influence the temperature in the treatment chamber for the substance to be thermally treated.

### BRIEF DESCRIPTION OF THE DRAWINGS

For a better understanding of the invention, it is explained in more detail with the aid of the following figures.

These show respectively in a simplified schematic representation:

FIG. 1 a device for the thermal treatment of a substance;

FIG. 2 a section of a device for providing a plasma;

FIG. 3 a detail of an embodiment variant of a device for providing a plasma;

FIG. 4 a section of a further embodiment variant of a device for providing a plasma;

FIG. 5 a section of a further embodiment variant of a device for providing a plasma;

FIG. 6 an arrangement of several plasma-generating elements;

FIG. 7 another arrangement of several plasma-generating elements;

FIG. 8 a jet pump in longitudinal section;

FIG. 9 a section of an embodiment variant of the device for providing a plasma;

FIG. 10 an embodiment variant of a device for the thermal treatment of a substance;

FIG. 11 a further embodiment variant of a device for the thermal treatment of a substance.

### DETAILED DESCRIPTION OF EXEMPLARY EMBODIMENTS

By way of introduction, it should be noted that in the various embodiments described, the same parts are provided with the same reference signs or the same component designations, wherein the disclosures included in the entire description may be transferred analogously to the same parts with the same reference signs or the same component designations. The position details chosen in the description, such as top, bottom, side, etc., also refer to the directly described and illustrated figure and these position details are to be transferred to the new position accordingly in the event of a change of position.

In the following, a first and a second gaseous fluid as well as a further gaseous fluid are listed. These fluids may be different gases or the same gases. The gaseous fluids may also be pure gases or gas mixtures.

In addition, the terms fresh gas, circulating gas, exhaust gas and process gas (also referred to as plasma gas) are used below. The fresh gas and the process gas may be formed by at least one of the gaseous fluids mentioned in the preceding paragraph. As the name suggests, the circulating gas is circulated in the device and reused to generate plasma. It therefore turns from exhaust gas back into process gas.

The terms “hot fluid” and “hot fluid flow” are also used in this description. For the purposes of the description, these terms are used both for a plasma flow which is directed directly onto a material to be treated and for a hot gas flow, i.e. a gas flow which is heated with a plasma and which is subsequently directed onto the material to be treated or is used for thermal treatment of the substance.

All gases suitable for forming a plasma may be used as gaseous fluids, such as nitrogen, argon, neon, xenon, air, carbon dioxide, carbon monoxide, hydrogen, gaseous water, or a mixture of at least two of these gases.

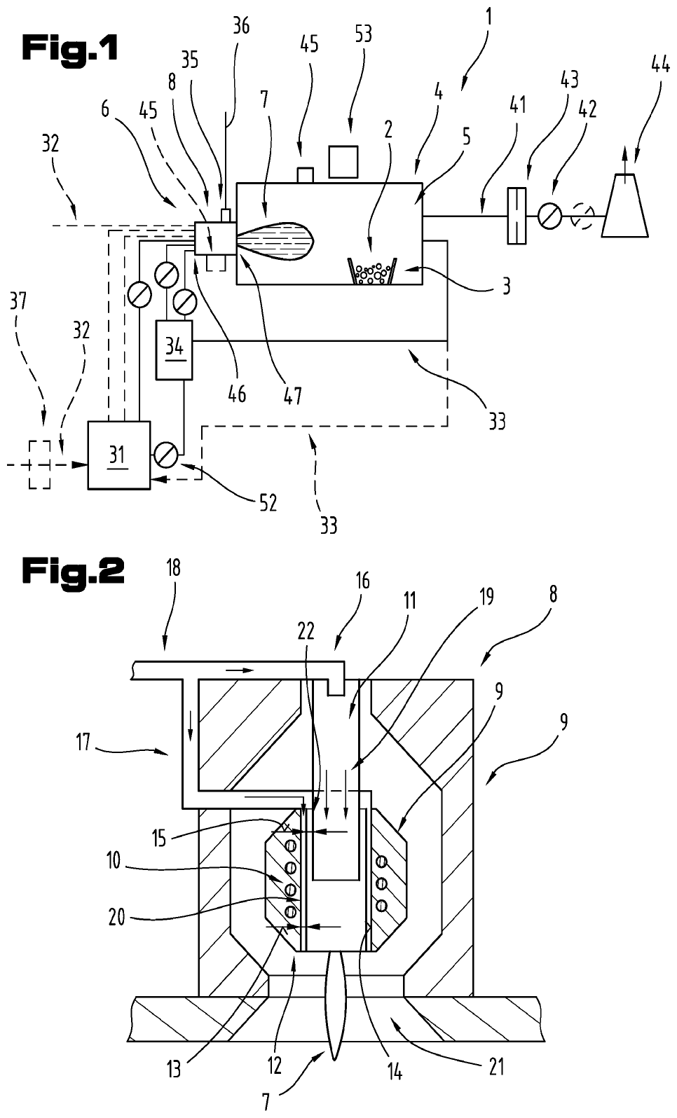

FIG. 1 shows a device 1 for the thermal treatment (hereinafter referred to simply as device 1) of a substance 2.

The substance 2 may be a liquid or a gas. Preferably, however, the substance 2 is a solid, in particular a metallic solid.

The thermal treatment can be the melting of the substance 2 or the temperature control of the substance 2, for example maintaining a certain temperature, or the heating of the substance 2. However, thermal treatment may also comprise a chemical reaction carried out at an elevated temperature. This list of possible uses of the device 2 is only intended as an example, with the melting of a metallic solid being one of the preferred applications.

Since the areas of application of the device 1 are different, the schematic diagram in FIG. 1 is not to be understood as limiting, but only as illustrating an exemplary embodiment.

The apparatus 1 comprises a receiving space 3 for the substance 2. The receiving space 3 may be formed by a separate container in which the substance 2 is disposed. In the case of a gas or in general, however, the receiving space 3 may also be only a housing 4 of a treatment chamber 5 or a chamber of the treatment chamber 5 in which the substance 2 for the thermal treatment is disposed. The aforementioned separate container, if present, is also arranged in the treatment chamber 5.

Just for the sake of completeness, it should be noted that more than one receiving space 3 for the substance 2 may also be arranged in the treatment chamber 5, wherein different substances 2 may also be accommodated in the receiving spaces 3, for example in order to carry out a chemical reaction.

Furthermore, the apparatus 1 comprises a device 6 for providing a plasma (hereinafter only referred to as a device 6), with which the thermal energy for the thermal treatment of the substance 2 is provided. The device 6 is arranged on the housing 4 of the treatment chamber 5 in such a way that a plasma torch or a plasma flow or a hot gas flow 7, which is generated with the plasma from the process gas, extends into or in the direction of the treatment chamber 5.

For further components of the device 1 which are not mentioned or described below, reference is made to the relevant prior art in order to avoid repetition.

The device 6 comprises at least one plasma-generating element 8.

An embodiment variant of the plasma-generating element 8 (also known as a plasma torch) is shown in FIG. 2 in longitudinal section.

The plasma-generating element 8 is provided with an element body 9 (also referred to as a torch body). At least one electric induction coil 10 for plasma generation is arranged in or on the element body 9. Several induction coils 10 may also be used, which may be designed to be adjustable and/or controllable independently of one another. The several induction coils 10 may be arranged one behind the other in the direction of flow of the gaseous fluid(s).

Plasma may also be generated in other ways, for example by means of a magnetron or generally with microwaves (e.g. generated by a solid state microwave generator) or by means of two electrodes, etc.

Furthermore, a first flow channel 11 for a first gaseous fluid and a concentrically arranged second flow channel 12 for a second gaseous fluid are arranged in the element body 9. The first flow channel 11 is arranged at least in sections, for example in the area above or in a partial area of the arrangement of the induction coil 10 within the second flow channel 12. The first and second flow channels 11, 11 may be tubular, for example with a circular cross-section. The first and/or the second flow channel 11, 11 may be formed, for example, from a quartz glass tube or an aluminum oxide tube or a boron nitride tube, etc.

The second flow channel 12 may be arranged at a distance 13 from a surface 14 of the element body 9 (in particular that surface 9 behind which the induction coil 10 is arranged), which is selected from a range from 0 mm to 30 mm, in particular from 0 mm to 20 mm.

The first flow channel 11 may be arranged at a radial distance 15 from the second flow channel 12, which is selected from a range of 0.1 mm to 40 mm, in particular 0.4 mm to 30 mm. The speed of the protective gas flow 20 can also be adjusted via the distance.

The first flow channel 11 has a first connection 16, i.e. a first supply, for the first gaseous fluid and the second flow channel 12 has a second connection 17, i.e. a second supply, for the second gaseous fluid. As may be seen from FIG. 2, the first and second connections 16, 17 may be fed from a common supply line 18 for the gaseous fluids. However, there may also be completely separate/independent supplies for the first and second gaseous fluids.

The first gaseous fluid is supplied to the first flow channel 11 via the first connection 16 to form a heated gas flow (central gas flow 19). Via the second connection 17, the second gaseous fluid is supplied to the second flow channel 12, which forms a protective volume flow (protective gas flow 20) between the surface 14 of the plasma-generating element 8, i.e. the element body 9, and the heated gas flow or the plasma flow. Both gas flows, i.e. the central gas flow 19 and the protective gas flow 20, leave the plasma-generating element 8 together via an outlet 21, i.e. an outflow opening, in order to be available for the thermal treatment of the substance 2.

It should be noted that the illustration of the plasma-generating element 8 in FIG. 2 is exemplary. The specific arrangement of the individual elements in the plasma-generating element 8 may also be configured differently, as long as the functionality is retained.

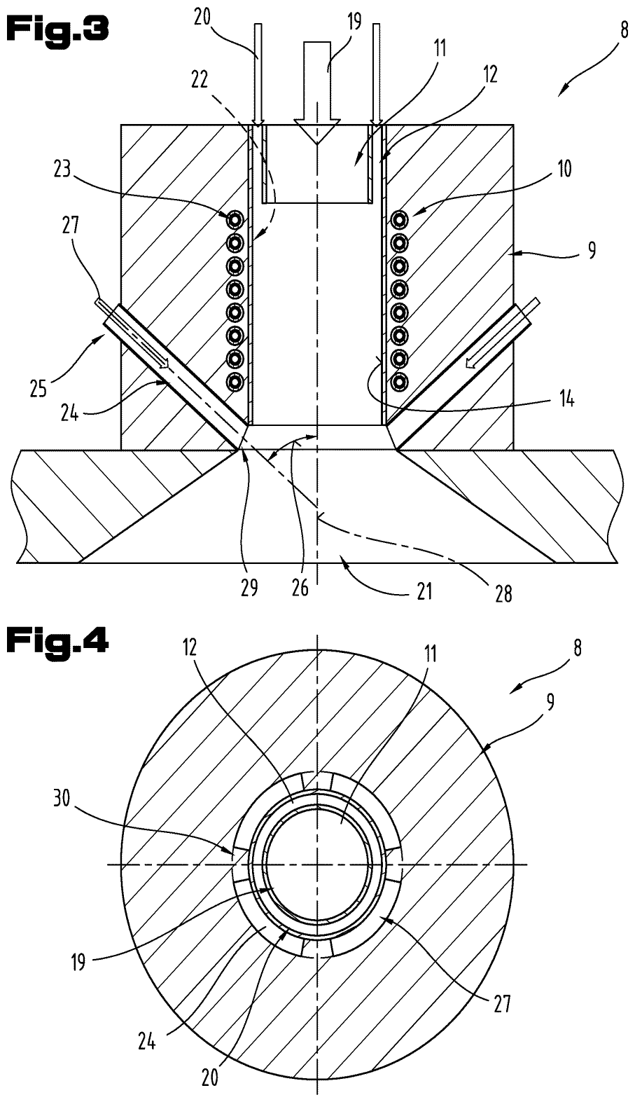

FIG. 3 shows a further and possibly independent embodiment of the plasma-generating element 8 in longitudinal section and in a schematic representation, again using the same reference signs or component designations for the same parts as in FIGS. 1 and 2. To avoid unnecessary repetition, reference is made to the previous description.

As may be seen from FIG. 3, the first flow channel 11 ends at a distance from the outlet 21 of the plasma-generating element 8, which, among other things, can improve the effect of the induction coil 10 on the central gas flow 19. The specific distance to the outlet 21 depends on the respective design of the plasma-generating element 8.

It may also be seen that no separate channel element (tube) is used for the second flow channel 12, but that according to an embodiment variant of the plasma-generating element 8, the second flow channel 12 is bounded on the outside by the surface 14 of the element body 9 of the plasma-generating element 8, i.e. is formed by the plasma-generating element 8 itself. Alternatively, it may be provided that the second flow channel 12 is formed by a separate channel element 22, as is the case in the embodiment according to FIG. 2 and is shown in stroke-dotted lines in FIG. 3, but this channel element 22 is arranged directly adjacent to the surface 14 of the element body 9. If necessary, this channel element 22 may also be formed as a coating on the surface 14 of the element body 9. The coating may, for example, be at least partially made of silver, gold, aluminum, etc. Of course, the spaced arrangement of the channel element 22 shown in FIG. 2 is also conceivable in the embodiment of the plasma-generating element 8 according to FIG. 3.

FIG. 3 also shows that the induction coil 10 may be arranged at a small distance from the surface 14 of the element body 9. Furthermore, FIG. 3 shows that the induction coil 10 may be cooled, for which purpose it may have a cooling channel 23. The cooling medium that can flow through the cooling channel 23 may be water, a cooling oil, etc., for example.

In the embodiment variant of the plasma-generating element 8 according to FIG. 3, it is provided that at least one further flow channel 24 is arranged or configured in the plasma-generating element 8. For example, the additional flow channel 24 may be configured in the element body 9 of the plasma-generating element 8. The further flow channel 24 is fluidically connected to a further connection 25 for a further gaseous fluid. If necessary, the further connection 25 may also be connected to the supply line 18 (see FIG. 2) so that all three gaseous fluids are composed in the same way. However, it is also conceivable to supply the other gaseous fluid completely independently of the supply of the first and second gaseous fluids.

As may be seen from FIG. 3, the further flow channel 24 is configured to run at an angle to the first flow channel 11 and to the second flow channel 12, an angle 26 between the flow channels 11 or 12 and 24 being configured such that a flow direction of a gas flow formed by the third fluid, in particular a cooling gas flow 27, runs in the direction of the center or in the direction of a longitudinal central axis 28.

In FIG. 3, the further flow channel 24 runs over its entire length in the plasma-generating element 8, i.e. in the element body 9, with the same angle of inclination. However, it may also be provided that only one end section is configured with the angle 26 at an angle. The end section begins at an outlet opening 29 of the further flow channel 24 in the plasma-generating element 8. The further flow channel 24 may therefore be configured with different angles of inclination over its length or the further flow channel 24 may also have a curved shape.

The further flow channel 24 enables the supply of the further gaseous fluid to change the temperature of the hot gas flow 7 or plasma flow formed from the protective gas flow 20 and the central gas flow 19. If necessary, the position of the hot gas flow 7 or the plasma flow or the plasma torch may also be changed.

According to a preferred embodiment variant of the plasma-generating element 8, the angle 26 that at least the end section of the further flow channel 24 includes with the first and second flow channels 11, 12 may be selected from a range of 10° and 80°, in particular from a range of 15° to 70°. For example, the angle 26 may be 20° or 30° or 40° or 45° or 50° or 60°.

Within the scope of embodiments in accordance with the present disclosure, it is conceivable that only a single further flow channel 24 is configured. As shown in FIG. 4, which shows a top view of a section of an embodiment variant of the plasma-generating element 8 in cross-section, several further flow channels 24 may be provided, for example four or only two or three or more than four, for example five or six, etc. The several further flow channels 24 are arranged distributed along a circumference defined by the second flow channel 12, in particular evenly distributed or symmetrically distributed. Webs 30 of the element body 9 may be configured between the individual further flow channels 24.

It should be mentioned at this point that the second flow channel 12 may also be divided into several second flow channels 12, which are distributed around the circumference of the first flow channel 11.

As shown in FIG. 4, each of the several further flow channels 24 extends over a circular ring segment (or circular ring section). According to an embodiment variant of the plasma-generating element 8, the circular ring segments may be selected from a range of 2° to 88°. For example, the circular ring segments may extend over a range of 10° to 80° or a range of 20° to 70°. However, a single circular ring segment may also extend over a range of 10° to 358°. In general, circular ring segments may extend over a range from 2° to a value defined by 360°/number of circular ring segments −1°, in particular up to a value defined by 360°/number of circular ring segments −5°.

The several circular ring segments may all have the same length in the circumferential direction. However, at least one of the circular ring segments may also have a different length in the circumferential direction to the other circular ring segments.

As may be seen from FIG. 1, according to a further embodiment of the device 6, it is conceivable for it to have a gas supply device 31. It is conceivable for the plasma-generating element 8 to be supplied not only with the first gaseous fluid, but also with the second and the further gaseous fluid from the gas supply device 31, as indicated by the stroke-dotted lines in FIG. 1. For this purpose, the first connection 16 for the first gaseous fluid and the second connection 17 for the second gaseous fluid and/or the further connection 25 for the further gaseous fluid may be fluidically connected to the gas supply device 31.

However, it is also conceivable that some or each of the connections 16, 17 and 25 is fluidically connected to a separate gas supply device 31.

Thus, the first connection 16 for the first gaseous fluid and the second connection 17 for the second gaseous fluid and the further connection 25 for the further gaseous fluid may each be supplied with the same gaseous fluid or at least two of them or all of them may be supplied with different gaseous fluids. For example, the first connection 16 may be supplied with a fresh gas and the second connection 17 and/or the other connection 25 with a circulating gas. Thus, according to a further embodiment variant of the device 6, it may be provided that at least one fresh gas supply 32 and at least one circulating gas supply 33 open into the gas supply device 31 to provide at least a portion of at least one of the gaseous fluids, as shown in stroke-dotted lines in FIG. 1. The circulating gas supply may be connected to the apparatus 1 for thermal treatment of the substance 2, in particular a furnace, into which the hot gas or plasma generated by the plasma-generating element 8 can be introduced.

According to another embodiment variant of the device 6, it may be provided that the circulating gas is introduced directly into the plasma-generating element 8, without the detour via the gas supply device 31, as shown in full lines in FIG. 1.

According to another embodiment variant of the device 6, it may be provided that at least one conveying element 34, for example a jet pump, for the circulating gas is arranged in the circulating gas supply. With regard to the conveying element 34, reference is made to the following explanations.

According to a further embodiment variant of the device 6, it may be provided that the plasma-generating element 8 has a connection 35 for an ignition gas 36, for example argon, in order to improve or accelerate the creation of the plasma or to be able to feed less suitable gases into the device 6 for the provision of the plasma.

According to an embodiment variant of the device 6, it may also be provided that at least one heat exchanger 37 for heating the newly supplied gaseous fluid (the fresh gas) is arranged in the fresh gas supply 32. The heat exchanger may be configured according to the state of the art.

It should be mentioned at this point that in FIG. 1 the fresh gas supply 32 is connected to the gas supply device 31. However, it may be provided that, alternatively or additionally, the fresh gas supply 32 is connected directly to the plasma-generating element 8, as shown in stroke-dotted lines in FIG. 1.

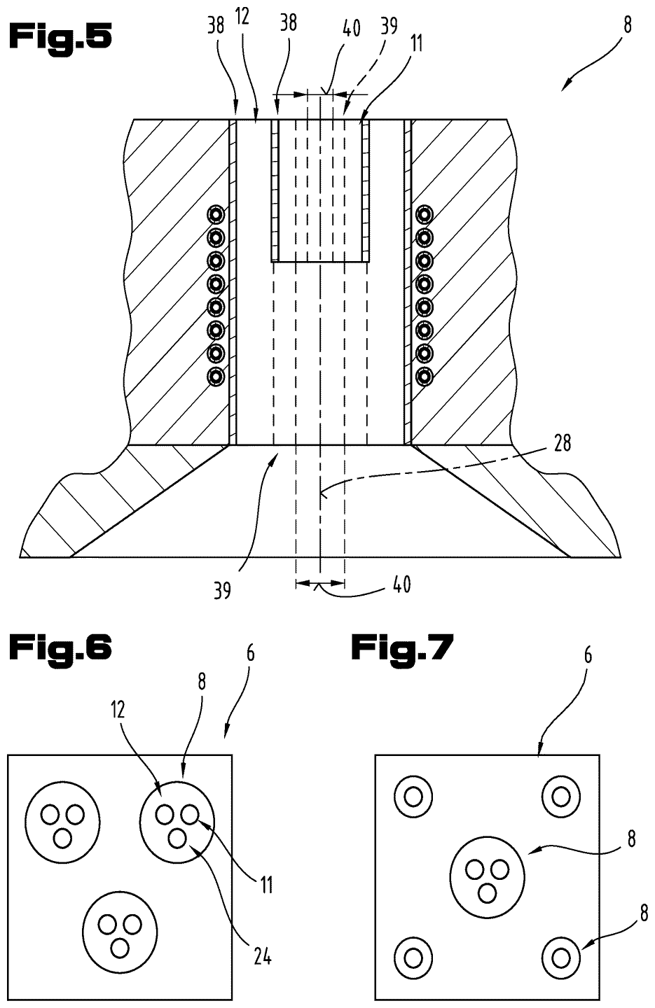

FIG. 5 shows a further and possibly independent embodiment of the plasma-generating element 8 in longitudinal section and in a schematic representation, again using the same reference signs or component designations for the same parts as in FIGS. 1 to 4. To avoid unnecessary repetition, reference is made to the previous description.

In this embodiment variant of the device 6 or the plasma-generating element 8, it is provided that the first flow channel 11 and/or the second flow channel 12 have a reflective coating 38 on the inside. This coating 38 may extend over the entire length or only a partial area of the length of the first flow channel 11 and/or the second flow channel 12, for example only in an beginning area or an end area and/or a middle area of the first flow channel 11 and/or the second flow channel 12. The coating 38 may also consist of differently composed sections in order to better correspond to the temperature distribution in the plasma-generating element 8, since the radiation maxima occur at different wavelengths according to the temperature. The radiation maxima thus shift to shorter wavelengths at higher temperatures. In this way, a material for coating sections that is particularly effective at the respective maximum radiation may be selected according to the respective wavelength or wavelength range. For example, an aluminum coating may be more effective than a gold or silver coating at shorter wavelengths. With longer wavelengths, this may be exactly the opposite.

The coating 38 may have a metallic configuration, for example. For example, the coating 38 may be formed by silver, gold, platinum, aluminum, or an alloy with at least one of these metals. This makes it possible, among other things, to adjust or change or increase the quantity of reflected radiation and/or the wavelength range of the reflected radiation. In particular, alloys or alloying elements may also be used to cover the wavelength range of the reflected radiation to wavelengths of less than 500 nm or less than 200 nm in order to increase the portion of reflected radiation in this wavelength range.

In addition to the circumferential full-surface configuration of the coating 38, according to an embodiment variant it is also conceivable to configure it in the form of strips or columns, as indicated in FIG. 5 by the strips 39 in stroke-dotted lines. The strips 39 may have a width in the circumferential direction of the first flow channel 11 or the second flow channel 12, which is selected from a range between 0.1% and 20%, in particular between 1% and 10%, of the circumference of the first flow channel 11 or the second flow channel 12.

The strips 39 may be arranged at a distance 40 from one another, which is selected from a range between 0.1% and 20%, in particular between 1% and 10%, of the circumference of the first flow channel 11 or the second flow channel 12.

It may further be provided that only a partial area of the circumference or the entire circumference is provided with spaced-apart strips 39 of the first flow channel 11 or the second flow channel 12.

The strips 39 may all be made of the same material. However, they may also made of different materials; for example, strips 39 made of metals with different reflective strengths may be combined in a plasma-generating element 8. Different materials may also be provided for the continuous coating 38 by forming it in sections from different materials, as described above.

The strips 39 have a longitudinal extension in the direction of the longitudinal center axis 28 through the first flow channel 11. According to an embodiment variant, the strip shape of the coating 38 may also be achieved by one or more helical configurations, wherein here again spacings may be configured between the coated sections (e.g. in the form of a helical, uncoated section).

The strips 39 may be configured as a coating 38. However, they may also be manufactured as separate components and subsequently connected to the first flow channel 11 or the second flow channel 12. The same applies to the coating 38 itself, in that it is produced as a tube and this is inserted into the first flow channel 11 or the second flow channel 12. It is also conceivable for the first flow channel 11 or the second flow channel 12 to be made of a correspondingly reflective material or with a correspondingly reflective surface, e.g. due to a configured surface structure.

FIGS. 6 and 7 show further and possibly independent embodiments of the device 6 in a schematic representation and as a section, again using the same reference signs or component designations for the same parts as in FIGS. 1 to 5. To avoid unnecessary repetition, reference is made to the previous description.

In the above explanations of the device 6, it only ever had one plasma-generating element 8. However, it is also conceivable for several plasma-generating elements 8 to be arranged in the device 6. For this purpose, embodiment variants with three or five plasma-generating elements 8 are shown as examples in FIGS. 6 and 7. Only two or four or more than five, for example six, etc., plasma-generating elements 8 may also be arranged in a device 6.

The plasma-generating elements 8 may all have the same heating power or a different heating power, as indicated in FIGS. 6 and 7 by the different sizes of the plasma-generating elements 8. Again, it should be noted that the specific illustrations should be understood as examples. Other embodiments are also possible, such as three plasma-generating elements 8 with the same heating power and one plasma-generating element 8 with a lower heating power compared to this, e.g. in order to be able to compensate for peak loads with this “smaller” plasma-generating element 8.

For example, for three plasma-generating elements 8 with a maximum power of 300 kW each (with three power feeds into the gaseous fluid), it may be provided that the plasma-generating elements 8 are operated at 100% power (300 kW each) for the desired 900 kW power, or that the plasma-generating elements 8 are operated at 78% power each for the desired 700 kW power, or that two plasma-generating elements 8 are operated at 100% power each and the third at 0% power at the desired 600 kW power, or that one plasma-generating element 8 is operated at 100% power each and the other two at 0% power at the desired 300 kW power. It may also be provided that at a maximum load of 400 kW, two plasma-generating elements 8 are operated at 100% power and one plasma-generating element 8 at 25% power. At a maximum load of 400 kW, two plasma-generating elements 8 may be operated at 0% power and one plasma-generating element 8 at 25% power in order to achieve 100 KW of desired power.

It should be noted that these examples are for illustrative purposes only and are not restrictive in nature.

The several plasma-generating elements 8 may all be configured in the same way, so that the explanations relating to the plasma-generating element 8 in this description may be applied to all plasma-generating elements 8.

According to an embodiment variant of the device 1, it may be provided that the treatment chamber 5 is fluidically connected to an exhaust gas line 41, wherein at least one flap 42 and/or at least one slide and/or at least one cross-section tapering element 43 is/are arranged in the exhaust gas line 41. The cross-section tapering element 43 may, for example, be configured as an orifice, possibly an adjustable orifice with a variable diameter of the passage opening.

With the at least one flap 42 or the at least one slide or the at least one cross-section tapering element 43, it is possible to control or regulate the volume flow of the exhaust gas leaving the device 1 via a discharging element 44, e.g. a chimney.

The rest of the exhaust gas becomes circulating gas and can be fed back into the process as such via the circulating gas supply 32. The portion that leaves the apparatus 1 through the discharging element 44 can be replaced with fresh gas via the fresh gas supply 33. It is therefore possible to control and/or regulate the volume flow ratio of circulating gas/fresh gas by means of the at least one flap 42 and/or the at least one slide and/or the at least one cross-section tapering element 43. It is also possible to regulate the pressure in the treatment chamber 5.

According to a further embodiment variant of the device 1, also shown in FIG. 1, it may be provided that the treatment chamber 5 and/or the device 6 for providing a plasma has/have a feeding device 45 for the introduction of solid particles which increase the thermal radiation. This feeding device 45 may be a nozzle, for example, so that the solid particles can be finely distributed in the treatment chamber 5 or the plasma-generating element 8 or the device 6 in general. The feeding device 45 may also have a different configuration.

The solid particles may be formed by graphite, a metal such as iron or copper or aluminum. Solid particles may also be used, which react with the substance 2 in the treatment chamber 5, for example to form an alloy. The solid particles may for example have an average particle size thickness of between 0.1 μm and 1000 μm.

The device 6 may be used to provide a plasma that can heat a gas flow so that the resulting hot gas flow 7 or the plasma flow itself can be used to thermally treat a substance 2. For this purpose, a gaseous fluid is introduced into at least one plasma-generating element 8 of the device 6 and a plasma is generated in the plasma-generating element 8. For better protection of the plasma-generating element 8, it is provided that the gaseous fluid in the plasma-generating element 8 is guided in the form of a central gas flow 19, which is surrounded by a protective gas flow 20.

It may be provided that a further gaseous fluid is mixed with the gaseous fluid formed from the protective gas flow 20 and the central gas flow 19 in the plasma-generating element 8, wherein the temperature and/or the position of a torch flare may be adjusted or controlled with the further gaseous fluid.

In order to regulate and/or control the apparatus 1 or the device 6, in particular the volume flows of the gaseous fluids, according to embodiment variants it may be provided that the temperature of the induction coil 10 and/or a temperature rise of the cooling liquid flowing through the cooling channel 23 of the induction coil 10 and/or a temperature change of the wall of the plasma-generating element 8 in the region of the hot gas outlet or plasma outlet from the plasma-generating element 8 is measured. This measured value may be used, for example, to change the volume flow of the central gas flow 20 in the event of a temperature change.

The temperature may be measured using known methods. For example, at least one thermocouple may be arranged in or on the wall of the plasma-generating element 8 in the area of the plasma gas outlet.

It is also conceivable that a temperature of the protective gas flow 20 is measured and that the volume flow of the inert gas flow 20 is changed based on this measured value in the event of a temperature change and/or that a gas pressure in the plasma-generating element 8 is controlled by changing the volume flow in the exhaust gas line 41 from a treatment chamber 5.

It is also conceivable for the temperature of the central gas flow 19 to be calculated and for at least one volume flow of the supplied gases, in particular the volume flow of the central gas flow 19, to be changed on the basis of this calculated value in the event of a temperature change. This may be calculated using the formula T_{calc}×cp_{calc}×ΣVᵢ=Σ(VᵢXTᵢ×cpᵢ)+P_{Induktion}. Here, T_{calc} is the calculated temperature, cp_{calc} is the calculated specific heat capacity of the hot fluid, ΣVᵢ is the sum of the volume flows, Σ(Vᵢ×Tᵢ×cpᵢ) is the sum of the products of the respective volume flow multiplied by the temperature of the respective volume flow x the specific heat capacity of the respective volume flow and P_{Induktion} is the inductively introduced power. The volume flows refer to the protective gas flow 20, the central gas flow 19 and the volume flow, if present, which is supplied via at least one further flow channel 24. The temperature to be calculated may be obtained by transforming the equation accordingly.

However, it is also possible to measure the temperature of the central gas flow 19, in particular to measure it without contact, for example using a pyrometer.

Features of the following embodiments may be implemented on their own or in combination with features of the preceding embodiments. In particular, dividing the gaseous fluid into the central gas flow 19 and a protective gas flow 20 is not absolutely necessary for subsequent embodiment variants of the device 6 or the apparatus 1.

In one embodiment, the device 6 for providing a plasma comprises at least one plasma-generating element 8 with at least one inlet 46 and one outlet 47 for a gaseous fluid, wherein the first flow channel 11 is arranged or configured in the plasma-generating element 8, optionally the second flow channel 12, which is arranged concentrically thereto and surrounds the first flow channel 11 at least in sections, the first flow channel 11 being fluidically connected to the one first connection 16 for a gaseous fluid for configuring a heated gas flow or a plasma flow. The at least one inlet 46 is formed by the connection 16 for the gaseous fluid. Since several gaseous fluids can be introduced into the plasma-generating element 8, as explained above, and this is also the preferred embodiment of the device 6 or the plasma-generating element 8, the plasma-generating element 8 may also have several inlets 46, via which the further gaseous fluids can be introduced into the plasma-generating element 8. Reference is made to the explanations above.

In this embodiment variant, the conveying element 34 for the gaseous fluid or several conveying elements 34 for gaseous fluids are also present or arranged. The conveying element 34 is or the conveying elements 34 are fluidically connected to the inlet 46 of the plasma-generating element 8.

Only one conveying element 34 is discussed in more detail below. If several conveying elements 34 are present, some of them or all conveying elements 34 may have the same configuration, so that the following explanations can also be applied to these conveying elements 34.

The gaseous fluid conveyed by the conveying element 34 can be accelerated or is accelerated by it.

According to embodiment variants, the plasma-generating element 8 may be fluidically connected to the gas supply device 31, which may preferably also have the fresh gas supply 32 and/or a circulating gas supply 33 for a circulating gas. The above explanations of these embodiment variants may be applied.

According to an embodiment variant, it may be provided that the conveying element 34 is arranged in a circulating gas flow for the circulating gas, which is fluidically connected to the outlet 47 of the plasma-generating element 8. In the embodiment of the device 1 according to FIG. 1, the outlet of the plasma-generating element 8 is not directly fluidically connected to the conveying element 34, but at least the treatment chamber 5 is arranged in between. Both embodiment variants, i.e. the direct flow connection of the outlet 47 with the conveying element 34 and the indirect flow connection of the outlet 47 with the conveying element 34 are possible, wherein the latter embodiment variant is the preferred one.

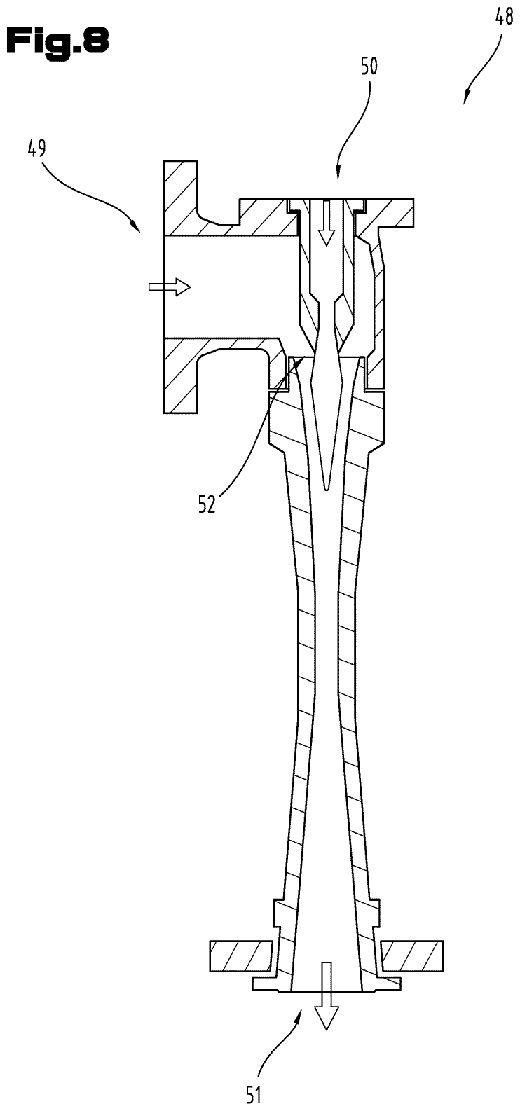

According to a preferred embodiment variant of the device 6, the conveying element 34 may be a jet pump 48 as shown as an example in FIG. 8.

The jet pump 48 has a first gas connection 49, a propellant connection 50 and an outlet 51. The first gas connection 49 may be connected to the fresh gas supply 32 or preferably to the circulating gas supply (see FIG. 1), so that fresh gas or circulating gas, which originates in particular from the exhaust gas of the treatment chamber 5, can be accelerated.

A propellant, in particular a gaseous propellant, is supplied to the propellant connection 50 under overpressure. This overpressure is converted into speed in the jet pump 48 by a cross-sectional narrowing 52, through which the propellant must pass. This creates an underpressure in the first gas connection 49, which entrains and accelerates the gas supplied there.

In principle, any suitable propellant may be used, although gaseous propellants are preferred. In the preferred embodiment of the device 6, however, a fresh gas is used as the propellant, which is also supplied to the plasma-generating element 8, so that the propellant connection 50 is connected to the fresh gas supply in this embodiment, for example via the gas supply device 31, as shown in FIG. 1.

According to an embodiment variant, it may be provided that the volume flow of the circulating gas flow is regulated with the volume flow of fresh gas supplied to the jet pump 48. This may be done, for example, via a control element 52, which is arranged in the fresh gas supply to the jet pump, as may also be seen in FIG. 1. The control element 52 may be, for example, a flap, a slide or a valve.

In general, it should be noted that the apparatus 1 or the device 6 may have a regulating and/or control device 53, to which the corresponding data can be provided wirelessly or by wire by the sensors of the apparatus 1 or device 6 and which can output the corresponding regulating and/or control signals, for example to change the volume flows of the process gases.

Alternatively or in addition to the control element 52, a controllable jet pump 48 may also be used to change or control the volume flows. For this purpose, the controllable jet pump 48 may be configured with a control of the volume or quantity flow of fresh gas that is supplied to the jet pump 48 as propellant.

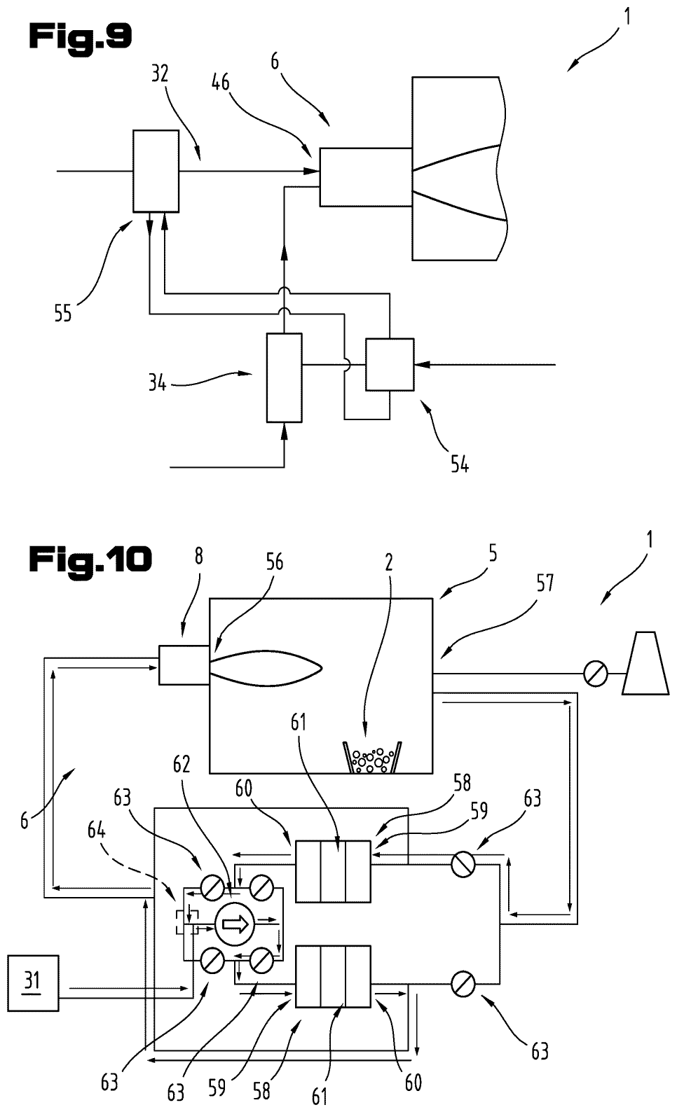

FIG. 9 shows a further and possibly independent embodiment of the device 6 for providing a plasma in a schematic representation, again using the same reference signs or component designations for the same parts as in FIGS. 1 to 8. To avoid unnecessary repetition, reference is made to the previous description.

In this embodiment variant, the inlet 46 of the plasma-generating element 8 is fluidically connected to a further fresh gas supply 32.

According to a further embodiment variant, a heat exchanger 54 is arranged upstream of the conveying element 34 in the direction of flow of the gaseous fluid, in particular the circulating gas.

Furthermore, according to an embodiment variant of the device 6, a further heat exchanger 55 may be arranged in the further fresh gas supply 32.

The heat exchanger 54 and the further heat exchanger 55 may be configured according to the state of the art.

It is also conceivable that the further heat exchanger 55 is fluidically connected to the heat exchanger 54 upstream of the conveying element 34. This allows the circulating gas to be cooled in the heat exchanger 54 and the thermal energy obtained in the process to be transferred to the fresh gas, which is supplied to the plasma-generating element 8 via the further fresh gas supply 32.

Alternatively, the heat exchanger 54 in the circulating gas supply 33 may also be connected to the heat exchanger 37 of the apparatus 1 (see FIG. 1) for transferring thermal energy.

By cooling the circulating gas upstream of the conveying element 34, it is also possible in particular to use conveying elements 34 that are less thermally resilient, such as a fan or a turbine according to an embodiment variant of the device 6.

Other conveying elements 34 that may be used are a pump, a vacuum pump, a compressor, an injector, etc.

According to an embodiment variant, it may be provided that at least one filter element is arranged upstream of the conveying element 34 in the direction of flow in order to be able to supply a purer gas to the conveying element 34. For example, abrasive loads or clogging of the conveying element 34 and the plasma-generating element 8 can be reduced or avoided.

Features of the following embodiments may be implemented on their own or in combination with features of the preceding embodiments. In particular, for the following embodiment variants of the device 1, it is not absolutely necessary to divide the gaseous fluid between the central gas flow 19 and the protective gas flow 20 and/or to use a conveying element 34.

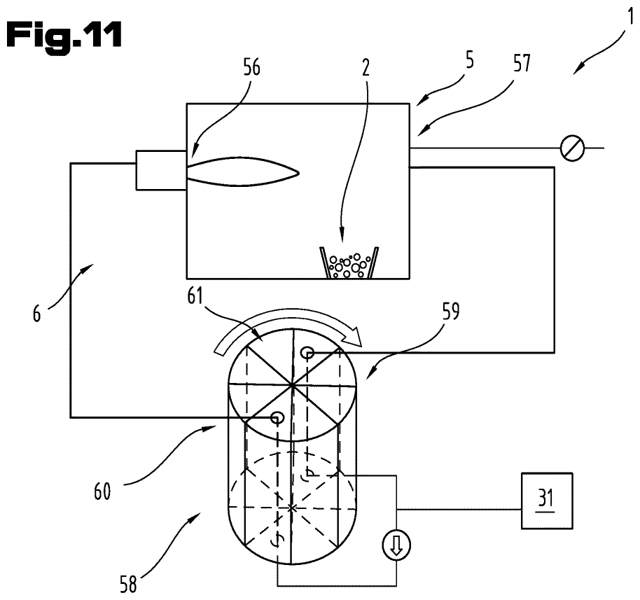

FIGS. 10 and 11 show further and possibly independent embodiments of the apparatus 1 in a schematic representation, again using the same reference signs or component designations for the same parts as in FIGS. 1 to 9. To avoid unnecessary repetition, reference is made to the previous description.

The apparatus 1 for the thermal treatment of the substance 2 of these embodiment variants again comprises the treatment chamber 5 and at least one device 6 for providing a plasma, wherein the treatment chamber 5 has an inlet 56 and an outlet 57 for the supply and discharge of a gaseous fluid into and out of the treatment chamber 5.

In both embodiment variants, it is provided that the outlet 57 of the treatment chamber 5 is fluidically connected to at least one heat exchanger 58, wherein the heat exchanger 58 has an inlet 59 and an outlet 60 for the supply and discharge of the gaseous fluid.

The gaseous fluid is preferably the exhaust gas from the treatment chamber 5, which is circulated through the apparatus 1.

The heat exchanger 58 has at least one heat storage element 61. The heat storage element 61 may, for example, be formed by a material based on or containing aluminum oxide (Al₂O₃), silicon dioxide (SiO₂), iron(III) oxide (Fe₂O₃), titanium dioxide (TiO₂), potassium oxide (K₂O), calcium oxide (CaO), sodium oxide (Na₂O), etc.

The at least one heat storage element 61 serves to absorb heat from the gaseous fluid that is passed through the heat exchanger 58 and to store it for later use.

In the embodiment shown in FIG. 10, at least one further heat exchanger 58 is provided, which also has at least one heat storage element 61. However, it is possible that only one heat exchanger 58 with at least one heat storage element 61 is present. In this case, the thermal energy extracted from the process gas and stored in the heat storage element 61 can be used for another process, for example. It is also possible for the thermal energy extracted from the process gas during cooling to be used as heating energy for space heating and/or water heating and/or to generate electricity. For this embodiment variant, it may be provided that the at least one heat exchanger 58 is arranged in a fluid circuit which connects the outlet 57 of the treatment chamber 5 to the inlet of the treatment chamber 56.

In the preferred embodiment variant, however, the gas that is added to the process gas, i.e. in this case the circulating gas, is reused in the process itself.

In the embodiment variant of the device 1, this is achieved by using at least two heat exchangers 58, each with at least one heat storage element 61. For this purpose, the hot circulating gas is fed from the outlet 57 into the first heat exchanger 58. In the illustration in FIG. 10, this is the upper of the two heat exchangers 58. The circulating gas is cooled in this first heat exchanger 58 and the extracted thermal energy is stored in its heat storage element 61.

After the first heat exchanger 58, the cooled circulating gas is fed into a gas conveying element 62, such as a fan or one of the aforementioned conveying elements 34. For this purpose, the outlet 60 of the first heat exchanger 58 may be fluidically connected to the gas conveying element 62. The gas conveying element 62 can build up the pressure to feed the circulating gas through the heat exchangers 68 or in the circuit.

If the circulating gas is still too hot for introduction into the gas conveying element 62, according to an embodiment variant of the device 1 it is possible for the circulating gas to be mixed with a cooler fresh gas upstream of the gas conveying element 62. For example, the fresh gas may be injected into the cooled circulation gas. The fresh gas may, for example, be supplied via the gas supply device 31. In this embodiment variant, a supply element for supplying a cooling medium, such as the fresh gas, into the gaseous fluid may be arranged in the device 1 upstream of the gas conveying element 62 in the direction of flow of the gaseous fluid.

In general, (pre-)cooling of the circulating gas may also take place at a different location. It is also possible for a partial flow of the circulating gas to be diverted and, if necessary, fed to a separate cooling system with a different heat exchanger in order to avoid thermal overloading of the heat storage elements 61. It may be provided that the separately cooled partial gas flow is supplied to the heat exchanger 58, i.e. to the at least one heat storage element 61, which is not heated, but which is (thermally) discharged.

According to another embodiment variant, it may alternatively or additionally be provided that a cooler fresh gas is already introduced into the hot circulating gas flow upstream of the inlet 59 or at the inlet 59, for which purpose a fresh gas supply may be arranged at the inlet 59 or upstream of the inlet 59 of the heat exchanger 58 for the gaseous fluid.

The gas conveying element 62 may also be arranged at a different position on the apparatus 1.

After the first heat exchanger 58, the cooled circulating gas, preferably with the gas conveying element 61, enters the second (lower) heat exchanger 58 via the inlet 59. The inlet 59 of the second heat exchanger 58 is connected to the outlet 60 of the first heat exchanger 58 directly or indirectly via the gas conveying element 61.

The at least one heat storage element 61 of the second heat exchanger 58 is already heated in normal operation, i.e. not in the start-up phase of the apparatus 1, so that the circulating gas is reheated in this second heat exchanger 58. This cools the heat storage element 61 of the second heat exchanger 58.

The heated circulation gas is fed back as process gas via the outlet 60 of the second heat exchanger 58, which is fluidically connected to the inlet 56 of the treatment chamber via the plasma-generating element 8. Before this, it is heated to the desired process temperature in the plasma-generating element 8.

This process continues until the first heat exchanger 58 reaches a critical temperature. This may, for example, be predefined by the temperature capacity of the gas conveying element 62.

At this point, the flow direction of the circulating gas is reversed. For this purpose, corresponding cycle flaps 63 or other suitable elements for changing the direction of flow of the gas may change their position accordingly, so that the exhaust gas from the treatment chamber 5 is subsequently guided first via the second (lower) heat exchanger 58 for cooling and then via the first (upper) heat exchanger 58 for reheating. In other words, in this cycle, the second heat exchanger 58 becomes the first heat exchanger 58 and the first heat exchanger 58 becomes the second heat exchanger 58. This cycle then proceeds again until the critical temperature is reached again and the cycle flaps 63 change their position again.

The corresponding wiring diagram for this cyclization is shown in FIG. 10.

Changing the position of the cycle flaps 63 or the aforementioned elements is preferably carried out fully automatically. For this purpose, a temperature sensor may be arranged in each of the heat exchangers 58, which supply corresponding measurement signals.

According to another embodiment variant of the device 1 shown in FIG. 11, it may be provided that the heat exchanger 58 has several heat storage elements 61 which are rotatably arranged so that the heat storage elements 61 can be alternately acted upon by the gaseous fluid, in particular the hot exhaust gas or the circulating gas, from the treatment chamber 5.

The hot gas or the hot exhaust gas (circulating gas) can be supplied via the upper part of the heat exchanger 58. In doing so, it transfers its heat to the heat storage elements 61, i.e. the respective heat storage element 61 in the correct rotational position. The cooled exhaust gas (circulating gas) is then fed back to the plasma-generating element 8 as process gas. Via the heat storage elements 61, the thermal energy reaches the lower part of the heat exchanger 58, which is also fixed, and can heat the cold fresh air supplied here. This becomes hot and the heat storage elements 61 cool down again and are available for a new load.

This process may be controlled via a temperature sensor, e.g. a thermocouple, in the cold exhaust gas. The amount of heat stored per heat storage element 61 may be specified via the speed of the heat exchanger 58.

The heated fresh gas can then be fed to the plasma-generating element 8.

In the illustration in FIG. 11, eight heat storage elements 61 are provided. However, fewer or more than eight heat storage elements 61 may also be used, for example three or four or five or six or seven or nine or ten, or significantly more than eight, such as more than 100, etc.

The heat storage elements 61 may be configured as honeycomb bodies, as spherical fill or generally as fill, as foam, as bodies produced by means of an additive method, etc. The permitted pressure loss, space requirement, etc. can be specified via the shape.

The heat storage elements 61 may be provided with a coating, for example a catalytic coating.

Since the heat or the thermal energy is preferably used again in the same process, it may also be provided in these embodiments that the at least one heat exchanger 58 is arranged in a fluid circuit which connects the outlet 57 of the treatment chamber 5 with the inlet 56 of the treatment chamber 5.

According to a further embodiment variant of the device, it may be provided that a third heat exchanger 64 is arranged upstream of the gas conveying element 62 in the direction of flow in order to further cool the gaseous fluid after it leaves the first heat exchanger 58. This third heat exchanger 64 may be configured without heat storage elements 61.

In the above explanations, it was assumed that apart from the partial volume flow, which is completely removed from the process via the discharging element 44, the remaining volume flow is cooled in its entirety. However, it is also possible for only part of the remaining volume flow to be cooled. In this case, this part can be used, for example, to cool components in the plasma-generating element 8.

The exemplary embodiments show possible embodiment variants, wherein combinations of the individual embodiment variants are also possible.

Finally, as a matter of form, it should be noted that for ease of understanding of the structure, elements are partially not depicted to scale and/or are enlarged and/or are reduced in size.

1. A device for providing a plasma, comprising at least one plasma-generating element with one inlet and one outlet for a gaseous fluid, wherein a first flow channel is arranged in the plasma-generating element, optionally a second flow channel which is arranged concentrically thereto and surrounds the first flow channel at least in sections, is arranged, the first flow channel being fluidically connected to a first connection for a gaseous fluid for forming a heated gas flow and/or a plasma flow, wherein the inlet of the plasma-generating element is fluidically connected to a conveying element with which the gaseous fluid can be accelerated, and the conveying element is a jet pump.

2. The device according to claim 1, wherein the plasma-generating element is fluidically connected with a gas supply device.

3. The device according to claim 2, wherein the gas supply device has a fresh gas supply and/or a circulating gas supply for a circulating gas.

4. The device according to claim 3, wherein the conveying element is arranged in a circulating gas flow for the circulating gas, which is fluidically connected to the outlet of the plasma-generating element.

5. (canceled)

6. The device according to claim 2, wherein the jet pump has a propellant connection which is connected to the fresh gas supply.

7. The device according to claim 1, wherein the jet pump is an adjustable jet pump with a regulation of the volume or quantity flow of fresh gas.

8. The device according to claim 1, wherein the inlet of the plasma-generating element is fluidically connected to a further fresh gas supply.

9. The device according to claim 1, wherein a heat exchanger is arranged upstream of the conveying element in the direction of flow of the gaseous fluid.

10. The device according to claim 9, wherein a further heat exchanger is arranged in the further fresh gas supply.

11. The device according to claim 10, wherein the further heat exchanger is fluidically connected to the heat exchanger upstream of the conveying element.

12. (canceled)

13. An apparatus for the thermal treatment of a substance comprising at least one device for providing a plasma, wherein the device for providing a plasma is formed according to claim 1.

14. A method for operating a device for providing a plasma for generating a hot gas flow and/or a plasma flow for thermally treating a substance, comprising the steps of:
supplying a gaseous fluid into a plasma-generating element of the device,
generating a plasma in the plasma-generating element, and
providing a hot fluid flow by the plasma, possibly by heating the gaseous fluid with the plasma to produce a hot gas, wherein the hot fluid flow is directed outside the plasma-generating element onto the substance to be treated, the gaseous fluid is accelerated before being supplied into the plasma-generating element, and the gaseous fluid is accelerated with a jet pump.

15. The method according to claim 14, wherein a further gaseous fluid is added to the gaseous fluid.

16. The method according to claim 15, wherein the temperature and/or the position of a plasma torch is adjusted or controlled with the further gaseous fluid.

17. The method according to claim 14, wherein the plasma is generated inductively with at least one electric induction coil and in that, furthermore, the temperature of the induction coil and/or a temperature rise of a cooling liquid for the induction coil and/or a temperature change of the wall of the plasma-generating element in the region of the hot gas outlet is measured and the volume flow of the gaseous fluid and/or a further gaseous fluid is changed on the basis of this measured value in the event of a temperature change.

18. The method according to claim 14, further comprising the steps of
supplying a fresh gas flow to a gas supply device of the plasma-generating element, and
supplying of a circulating gas flow from a treatment chamber, in which the substance is thermally treated, to the gas supply device, wherein the jet pump is used for the supply of the circulating gas flow, which is operated with a fresh gas flow as propellant gas.

19. The method according to claim 18, wherein the volume flow of the circulating gas flow is regulated with the volume flow of fresh gas supplied to the jet pump.
